(19) United States
(12) Patent Application Publication
(10) Pub. No.: US 2026/0363089 A1
(43) Pub. Date: Nov. 12, 2026

(54) POWER MODULE, ELECTRIC POWER CONVERTER AND ELECTRIC DRIVE FOR A TRANSPORTATION MEAN

(71) Applicant: VALEO EAUTOMOTIVE GERMANY GMBH, Erlangen (DE)

(72) Inventors: Alexander BUCHER, Erlangen (DE); Alexander PAWELLEK, Erlangen (DE)

(73) Assignee: VALEO EAUTOMOTIVE GERMANY GMBH, Erlangen (DE)

(21) Appl. No.: 19/137,878

(22) PCT Filed: Dec. 20, 2023
(86) PCT No.: PCT/EP2023/086995

§ 371 Date: Jun. 11, 2025

(30) Foreign Application Priority Data
Dec. 22, 2022 (DE) 10 2022 134 477.0

(51) Int. Cl. H10W 42/20; H10W 44/20; H10W 90/10

(52) U.S. Cl. CPC H10W 42/287; H10W 42/276; H10W 44/203; H10W 90/10

(57) ABSTRACT

Power module includes at least one arrangement of multiple dies each forming a transistor with a switching path. Each die has a first terminal, a second terminal and a control terminal. The switching path is formed between the first terminal and the second terminal and is switchable depending on a voltage across the control terminal and the second terminal. The transistors is connected in parallel by the first terminals being connected with each other and the second terminals being connected to each other. The at least one arrangement includes a shielding structure that covers at least two of the dies at least partially, and the shielding structure includes one material or multiple materials chosen from a group consisting of a nickel-zinc-based ferrite, a nickel-iron soft ferromagnetic alloy and an electrical steel.

### FIELD OF THE INVENTION

The present invention relates to a power module comprising at least one arrangement of multiple dies each forming a transistor with a switching path, each die having a first terminal, a second terminal and a control terminal, the switching path being formed between the first terminal and the second terminal and being switchable depending on a voltage across the control terminal and the second terminal, the transistors being connected in parallel by the first terminals being connected with each other and the second terminals being connected to each other.

Aside, the invention relates to an electric power converter and to an electric drive for a transportation mean, for example for a vehicle or for a bicycle.

### BACKGROUND OF THE INVENTION

I. Kovacevic-Badstuebner, U. Grossner, D. Popescu and B. Popescu, “Transient Stability Analysis of Discrete and Multi-chip Power Semiconductor Packages,” 2021 33^{rd} International Symposium on Power Semiconductor Devices and ICs (ISPSD), 2021, pp. 391-394, disclose parallel-connected power devices based on 650V SiC power MOSFETs and discuss high frequency oscillations occurring during fast switching transients.

With the increase of demand of power provided by traction inverters for electric transportation means, paralleling multiple dies has become necessary in order to cope with the corresponding current and loss densities. However, connecting the dies in parallel leads to very complex resonant systems with distinctive feedback loops. Corresponding oscillations can be expected in the VHF band, particularly above 100 MHz, and can trigger different failure mechanisms within a structure of the control terminals of the dies.

In order to reduce corresponding couplings in such feedback loops, I. Kasko, S. E. Berberich, M. Spang and S. Oehling, “SiC MOS Power Module in Direct Pressed Die Technology and some Challenges for Implementation,” 2020 32^{nd} International Symposium on Power Semiconductor Devices and ICs (ISPSD), 2020, pp. 364-367, propose to increase an internal gate resistance of parallel SiC MOS.

However, an increase of the resistance at the control terminal disadvantageously decreases the achievable switching speed of the power module and requires internal modifications of the dies. Also, integrating individual gate pre-resistors increases the complexity of the module's assembly process as well as the foot-print of the power module and, therefore, deteriorates reliability and power density of the electric power converter.

Further, it is known from DE 10 2019 202 728 A1 to provide a plate-shaped structure made of electrically conductive material to half-bridges of semiconductor switches. The plate-shaped structure is mounted with a distance to the half-bridge for reducing an intermediate circuit inductance by inducting eddy currents in the plate-shaped structure.

Further, US 2003/0011057 A1 discloses a semiconductor device having a semiconductor element and a bonding wire connecting the semiconductor element with an electrode. A sheet member is arranged above the bonding wire. A sealing resin member covers the electrode, the semiconductor element, the bonding wire and buries the sheet member. The sheet member reduces vibration of the sealing resin member.

### SUMMARY OF THE INVENTION

It is an object of the invention to improve the operation of a power module with parallelized dies, in particular with regard to a reduction of VHF oscillations.

According to the invention, this object is solved by a power module as initially described, in which the at least one arrangement comprises a shielding structure that covers at least two of the dies at least partially, the shielding structure comprising or consisting of one material or multiple materials chosen from a group consisting of a nickel-zinc-based ferrite, a nickel-iron soft ferromagnetic alloy and an electrical steel.

The power module according to the invention comprises the at least one arrangement of multiple dies. Each die forms a transistor with a switching path. Each die has a first terminal, a second terminal and a control terminal. The switching path is formed between the first terminal and the second terminal. The switching path is switchable depending on a voltage across the control terminal and the second terminal. The transistors are connected in parallel by the first terminals being connected with each other and the second terminals being connected to each other. The at least one arrangement further comprises a shielding structure. The shielding structure covers at least two of the dies at least partially. The shielding structure comprises or consists of one material or multiple materials. The material is or the materials are chosen from a group. The group consists of a nickel-zinc-based ferrite, a nickel-iron soft ferromagnetic alloy and an electrical steel.

The invention is based upon the consideration to reduce VHF oscillations caused by inductive feedback loops when parallelizing the dies by providing a shielding structure in order to influence the magnetic coupling between the first and second terminal and a control terminal loop and/or by attenuating the feedback loops. Therein, nickel-zinc-based ferrites provide suitable high frequency loss characteristics for attenuating the feedback loops. Further, it has been observed that a shielding structure made of or containing a nickel-iron soft ferromagnetic alloy and/or electrical steel also provides a significant reduction of the VHF oscillation amplitudes, although these materials are usually not known for their high frequency characteristics. Advantageously, the power module according to the invention allows to reduce the VHF oscillations, particularly without affecting the internal control terminal resistances and without reducing the maximum switching speed of the power module.

The group may be restricted to consist only of the nickel-zinc-based ferrite or only of the nickel-iron soft ferromagnetic alloy or only of the electrical steel or only of the nickel-zinc based ferrite and the nickel-iron soft ferromagnetic alloy or only of the nickel-zinc-based ferrite and the electrical steel or only of the nickel-iron soft ferromagnetic alloy and the electrical steel.

The number of dies may be at least two, preferably at least four, more preferably at least six. The transistor may be an insulated gate bipolar transistor (IGBT). In this case, the first terminal may be a collector terminal, the second terminal may be an emitter terminal and the control terminal may be a gate terminal.

Alternatively, the transistor may be a metal oxide semiconductor field effect transistor (MOSFET), preferably based on silicon carbide (SIC), or a high-electron-mobility transistor (HEMT), particularly based on gallium nitride (GaN). With regard to MOSFETs and HEMTs, the first terminal may be a drain terminal, the second terminal may be as source terminal and the control terminal may be a gate terminal. Preferably, the transistor is configured to block voltages of at least 400 V, preferably at least 800 V, more preferably at least 1200 V, over the switching path. However, the invention may be also applied to low-voltage power modules, e.g. in 48-volt-systems, where the transistor is configured to block voltages of at least 50 V.

In detail, electrical connections between the dies may form a resonant circuit with one or multiple resonance frequencies of at least 100 MHz and feedback loops that form an inductive coupling between the second terminals on the one hand and the first terminals and/or control terminals on the other hand. Then, the shielding structure may be configured to reduce the inductive coupling. The shielding structure may thus be specifically adapted to reduce the inductive coupling between feedback loops connected to the first and second terminals (output loops) and/or feedback loops connected to the control terminal and the second terminal (input loops) in the afore-said frequency range. Especially, the at least resonance frequency may be situated between 100 MHz and 1 GHz.

With regard to the nickel-zinc-based ferrite, it has preferably a complex permeability with a real part and an imaginary part. The complex permeability u of the nickel-zinc-based ferrite may thus be expressed by

$$\underline{μ} = {μ}_{0} \cdot ( {μ}_{r}^{′} - j \cdot {μ}_{r}^{″} )$$

with μ₀ denoting the vacuum magnetic permeability,

$${μ}_{r}^{′}$$

denoting the real part of the relative permeability,

$${μ}_{r}^{″}$$

denoting the imaginary part of the relative permeability and j denoting the imaginary unit.

Desirably, within a frequency range between 10 MHz and 1 GHz, preferably between 100 MHz and 1 GHz, there is a maximum of the imaginary part. Having the maximum of the imaginary part within or close to the expected oscillation frequencies, provides a high attenuating effect on the oscillations so that a nickel-zinc-based ferrite having the maximum within this range is favorized.

Alternatively or additionally, at a frequency of 100 MHz, preferably 50 MHz, more preferably 10 MHz, the real part of the complex permeability is reduced compared to its value for frequencies approaching zero. Particularly, the real part is reduced by a factor two, preferably a factor 10. It has been observed that a relatively high value of the real part may even amplify the oscillations due to the corresponding increase in magnetic flux linkage and an increase of feedback. Thus, it is preferred to choose a nickel-zinc-based ferrite, whose real part of the complex permeability is already decreasing at the afore-said frequency. It should be noted that there is a relationship between the real part of the complex permeability of the ferrite and a corner frequency according to Snoek's law saying that the corner frequency is lower the higher the real part of the complex permeability is. It has been found out that suitable values of the real part of the complex for frequencies approaching zero permeability are lower than 300, preferably 100, more preferably 30.

Altogether, it is desirable to choose a nickel-zinc-based ferrite with a high value of the imaginary part of the complex permeability and at the same time a low value of the real part of the complex permeability so as to provide a high attenuation efficiency.

The soft-magnetic nickel-iron-alloy may be mu-metal or permalloy. The nickel-iron alloy may comprise A wt.-% of nickel, B wt.-% of iron and C wt.-% of a metal with A+B+C≤100, 75≤A≤80, 15≤B≤20, 2≤C≤5 and the metal being one or multiple metals chosen from a group consisting of copper, chrome, molybdenum and cobalt. Such an alloy is commercially available but commonly not used in high frequency applications or EMI applications.

The electrical steel may be a, particularly non-grain-oriented, silicon steel. The electrical steel may comply with EN 10106:2015 or EN 10107:2014. Such a steel is commonly used as sheet material in transformer or motor applications but not in applications referring to the VHF range or above.

In general, the shielding structure may be plate-shaped. I.e., the shielding structure may cover the at least two dies in two spatial directions and may have a low thickness in the perpendicular spatial direction. Typically, the shielding structure has a thickness of less than 5 mm, preferably less than 2 mm, more preferably less 1 mm or even less than 0.5 mm.

In general, the at least one arrangement may further comprise an electrically conductive first pad, to which the second terminals are connected. The power module may also comprise an electrically conductive second pad, to which the first terminals are connected, and/or an electrically conductive trace, to which the control terminals are connected, and/or an electrically conductive further pad of the power module, to which further pad kelvin terminals of the dies are connected. Of course, the dies may have further terminals such as terminals for current sensing.

According to a first preferred design of the power module according to the invention, the shielding structure does not cover the die that has the smallest distance to the first pad. In this case, a die that is close to the first pad may not be covered as it forms only a relatively small feedback loop with regard to the second pad or the trace. Alternatively or additionally, the shielding structure does not cover the die that has the smallest distance to the further pad. In this case, a die that is close to the further pad may not be covered as it forms only a relatively small feedback loop to the trace. By not covering selected dies, material for the shielding structure can be saved advantageously.

According to a second preferred design of the power module according to the invention, the shielding structure covers each die at least partially. By covering all dies, a high attenuation efficiency can be achieved.

With regard to the power module according to the invention, it is further preferred that the shielding structure covers the at least two dies fully. By fully covering the respective dies, a high attenuation efficiency can be achieved as well.

The power module according to the invention may further comprise a carrier, on which the dies are mounted, the at least two dies being arranged between the carrier and the shielding structure. The carrier may be made of ceramics, therein realizing a direct bonded copper substrate (DBC), a direct bonded aluminum substrate (DBA) or an active metal brazed substrate (AMB). Alternatively, the carrier may be made of metal having a dielectric coating thereon. Such a carrier may realize an insulated metal substrate (IMS).

Also, the power module according to the invention may further comprise a single body formed by electrically insulating molding material, the body covering the dies and/or electrical connections, such as wire bonds, between the dies. The body may be used together with the carrier, by overmolding it. Also, the carrier may be omitted so that the body covers or embeds the dies and the electrical connection. Thereby, a transfer molded lead frame (TML) design may be realized. The body may further cover or embed the pads.

Preferably, the body embeds the shielding structure. Thereby, the position of the shielding structure may be fixed with regard to the dies or the connections, respectively, so as to provide stable attenuation properties.

The at least one arrangement may further comprise a support structure mounting the shielding structure. The support structure may provide a defined distance between the dies and the shielding structure, therein disposing the shielding structure at a position, where good attenuation properties can be achieved. It should be noted that the choice of the distance depends on various design details of the power module and should be made based on simulations or experiments.

In detail, the support structure may be mounted on the carrier. Further, the support structure may be a frame, upon which the shielding structure is arranged, or a multiplicity of domes each supporting the shielding structure selectively. In addition, the support structure may be electrically connected to the shielding structure. Thus, the support structure may be realized by different geometries, which facilitates to apply it to highly diverse power module designs.

Further, the support structure may be electrically insulating. Therein, the establishment of electrical connections between the shielding structure and other electrically conductive components may avoided. Nonetheless, it is possible that the shielding structure is connected to a suitable voltage potential of the power module, e.g., via the support structure, so as to additionally shield electric flux generated by switching actions of the dies for reducing electromagnetic emissions.

Preferably, a first arrangement and a second arrangement are provided, the first terminals of the first arrangement being connected to the second terminals of the second arrangement so as to form a half-bridge.

According to a further aspect, the present invention refers to a power module comprising at least one arrangement of multiple dies each forming a transistor with a switching path, each die having a first terminal, a second terminal and a control terminal, the switching path being formed between the first terminal and the second terminal and being switchable depending on a voltage across the control terminal and the second terminal, the transistors being connected in parallel by the first terminals being connected with each other and the second terminals being connected to each other, wherein the arrangement comprises a shielding structure that covers at least two of the dies at least partially, wherein electrical connections between the dies form a resonant circuit with one or multiple resonance frequencies of at least 100 MHz and feedback loops that form an inductive coupling between the second terminals on the one hand and the first terminals and/or control terminals on the other hand, the shielding structure being configured to reduce the inductive coupling. All afore-mentioned statements apply to this aspect analogously so that the respective advantages may be achieved as well.

The present invention further relates to an electric power converter, comprising: a DC port with for a DC voltage; an AC port with multiple phase conductors for an AC voltage; and a power section comprising a plurality of switching elements being interconnected to a half-bridge for each phase conductor, each half-bridge being connected between the DC port and each phase conductor being connected to a central tap between the switching elements of one of the half-bridges; wherein each switching element or each half-bridge is formed by a power module according to the invention.

The half-bridges may be connected to two lines of the DC port. Of course, there are other layouts so as to connect the half-bridges to the DC port.

The present invention further relates to an electric drive for a transportation mean, for example for a vehicle or a bicycle, comprising an electric machine configured to propel the transportation mean and an electric power converter according to the invention, the electric machine being connected to the AC port of the electric power converter for supplying the electric machine with the AC voltage.

### BRIEF DESCRIPTION OF THE DRAWINGS

Further details and advantages of the invention are disclosed in the following, wherein reference is made to the drawings, which show schematically:

FIG. 1 a partial top view on a first embodiment of a power module according to the invention;

FIG. 2 a top view on the power module according to the first embodiment;

FIG. 3 a cross-sectional view of the power module according to the first embodiment;

FIG. 4 a top view on a second embodiment of the power module according to the invention;

FIG. 5 diagrams of a gate-source voltage, a drain-source voltage and a drain-source current over time and of the gate-source-voltage over frequency for a power module without a shielding structure;

FIG. 6 diagrams of a gate-source voltage, a drain-source voltage and a drain-source current over time and of the gate-source-voltage over frequency for a power module with a shielding structure made of a manganese-zinc ferrite;

FIG. 7 diagrams of a gate-source voltage, a drain-source voltage and a drain-source current over time and of the gate-source-voltage over frequency for a power module according to the invention with a shielding structure made of a nickel-iron soft ferromagnetic alloy;

FIG. 8 diagrams of a gate-source voltage, a drain-source voltage and a drain-source current over time and of the gate-source-voltage over frequency for a power module according to the invention with a shielding structure made of electrical steel;

FIG. 9 a block diagram of an embodiment of an electric power converter according to the invention; and

FIG. 10 a principle drawing of an electric vehicle with an embodiment of an electric drive according to the invention.

### DETAILED DESCRIPTION

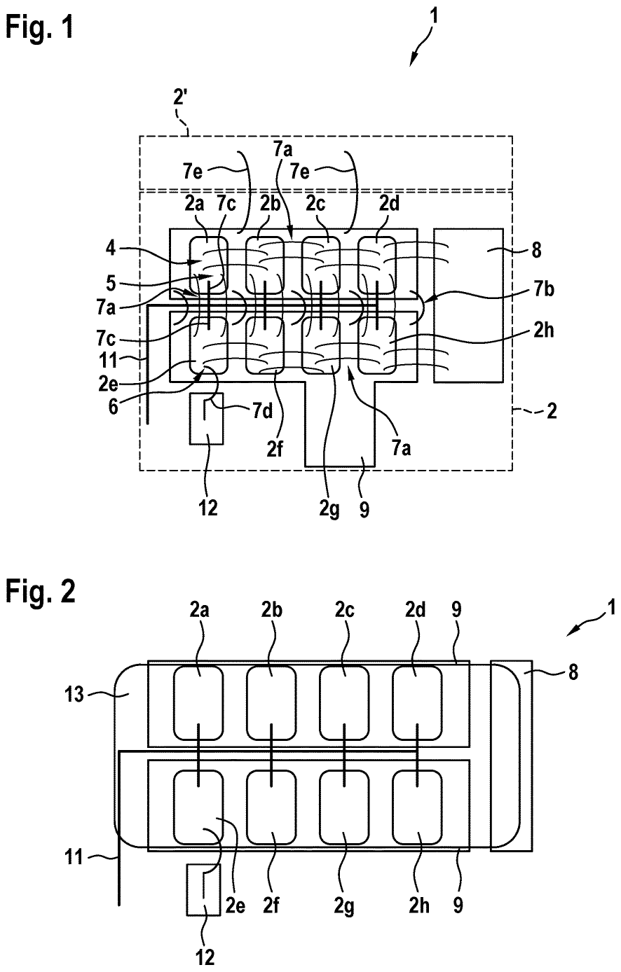

FIG. 1 is a partial top view on a first embodiment of a power module 1.

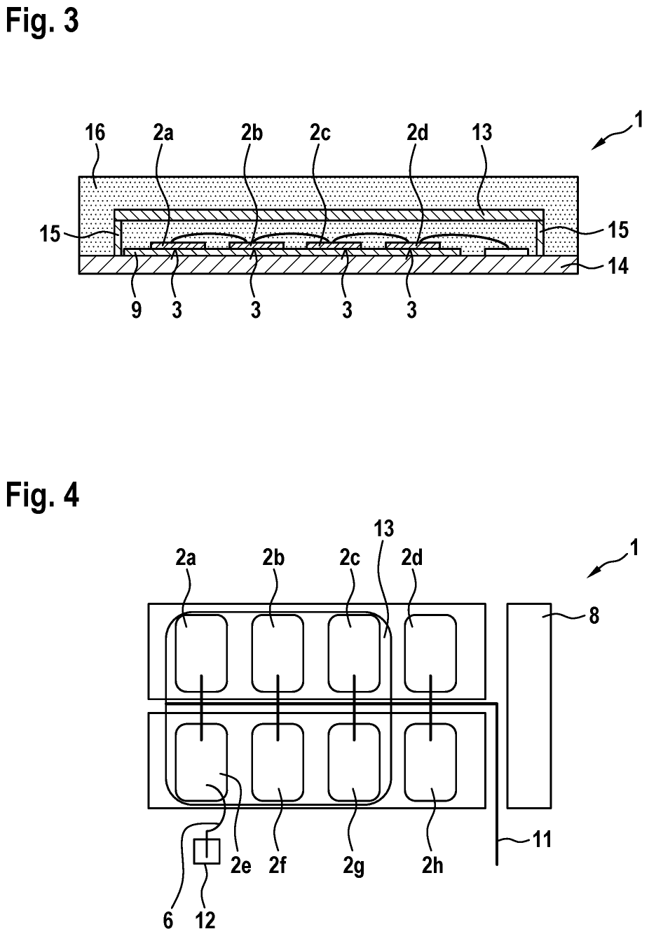

The power module 1 comprises a first arrangement 2 of multiple, here exemplary eight, dies 2a to 2h each forming a transistor with a switching path. Each die 2a to 2h has a first terminal 3 (see FIG. 3), a second terminal 4 and a control terminal 5. The switching path is formed between the first terminal 3 and the second terminal 4 and switchable depending on a voltage across the control terminal 5 and the second terminal 4. In the present embodiment the transistor is exemplarily realized as a SIC MOSFET with a maximum blocking voltage of 1200 V. Thus, the first terminal 3 is a drain terminal, the second terminal 4 is a source terminal and the control terminal is a gate terminal. Further, an optional kelvin terminal 6 is depicted in FIG. 1.

The transistors are connected in parallel by the first terminals 3 being connected with each other and the second terminals 4 being connected to each other. In the exemplary configuration depicted in FIG. 1, the second terminals 4 are connected by electrical connections 7a to an electrically conductive first pad 8 and the first terminals 3 are connected by being mounted on electrically conductive second pads 9 and by electrical connections 7b between the second pads 9. Further, the control terminals 5 are connected to an electrically conductive trace 11 by electrical connections 7c, therein forming a common control signal supply for the dies 2a to 2h. Just as an exemplary illustration, the trace 11 extends between the second pads 9 and the electrical connections 7b jump over the trace 11. The optional kelvin terminal is connected to a third pad 12 by electrical connections 7d. The afore-mentioned electrical connections 7a to 7d may be formed by wire bonds.

FIGS. 2 and 3 show the first arrangement 2, wherein FIG. 2 is a top view and FIG. 3 is a cross-sectional view.

The first arrangement 2 further comprises a plate-shaped shielding structure 13 that covers the dies 2a to 2h fully. The shielding structure 13 consists of a nickel-zinc-based ferrite, a nickel-iron soft ferromagnetic alloy or an electrical steel or of a combination of two or three of these materials. In the case of the nickel-zinc-based ferrite, a maximum of the imaginary part of its complex permeability is situated between 10 MHz and 1 GHz and at a frequency of 100 MHz, preferably 50 MHz, more preferably 10 MHz, the real part of the complex permeability is reduced compared to its value for frequencies approaching zero by a factor of two or even ten.

In the present embodiment the power module 1 further comprises a carrier 14 and the arrangement 2 further comprises a support structure 15. The carrier 14 is made of ceramics therein forming a direct bonded copper substrate (DBC) or an active metal brazed substrate (AMB) structure with the pads 8, 9 and the trace 11 being made of copper or forming a direct bonded aluminum substrate (DBA) with the pads 8, 9 and the trace 11 being made of aluminum. The dies 2a to 2h are arranged between the carrier 14 and the shielding structure 13. The support structure 15 is electrically insulating and mounts the shielding structure 13 at a predefined distance to the dies 2a to 2h. Thereto, the support structure 15 is a frame, upon which the shielding structure is arranged.

Further, the power module 1 comprises a single body 16 formed by electrically insulating molding material. The body 16 covers the dies 2a to 2h, the electrical connections 7a to 7d, the pads 8, 9, 12 and the trace 11. The body 16 also embeds the shielding structure 13 and the support structure 15.

Again with reference to FIG. 1, the power module 1 comprises a second arrangement 2′ corresponding to the first arrangement 2. The first terminals 3 of the first arrangement 2 are connected by further electrical connections 7e to the second terminals 4 of the second arrangement 2′ so as to form a half-bridge.

FIG. 4 is a detailed top view on the first arrangement 2 according to a second embodiment of a power module 1. The second embodiment corresponds to the first embodiment and differences therebetween are described in the following.

Identical or equivalent components are denoted by the same reference numerals. In comparison to the first embodiment, the trace 11 extends between first pad 8 and the second pad 9 and the shielding structure 13 covers only dies 2a, 2b, 2c, 2e, 2f, 2g. I.e., the shielding structure 13 does not cover dies 2d, 2h having the smallest distance to the first pad 8.

In this embodiment the shielding structure 13 may be smaller than in the first embodiment as feedback loops formed between the first terminals 3 of dies 2d, 2h and the first pad 8 are significantly smaller than the corresponding feedback loops between the first terminals 3 of other dies 2a, 2b, 2c, 2e, 2f, 2g and the first pad 8. On the other hand, it is possible not to cover dies 2d, 2h as feedback loops formed between the trace 11 and first pad 8 are significantly smaller than the corresponding feedback loops via the other dies 2a, 2b, 2c, 2e, 2f, 2g. Note that impact of the feedback loops between the first terminals 3 and the first pad 8 on the one hand, and the impact of the feedback loops over the trace 11 and the third pad 12 should be evaluated in detail so as to decide which of the dies 2a to 2h are not covered by the shielding structure 13.

According to a further embodiment, the carrier 14 is made of a metal having a dielectric coating (not shown) thereon, therein realizing an insulated metal substrate (IMS).

According to a further embodiment, a carrier is omitted and the body 16 covers or embeds the dies 2a to 2h, the electrical connections 7a to 7d, the pads 8, 9, 12 and the trace 11, therein forming a transfer molded lead frame (TML) design.

According to a further embodiment, the support structure 15 is a multiplicity of domes, each supporting the shielding structure 13 selectively. In addition, the support structure 15 may be electrically connected to the shielding structure 13.

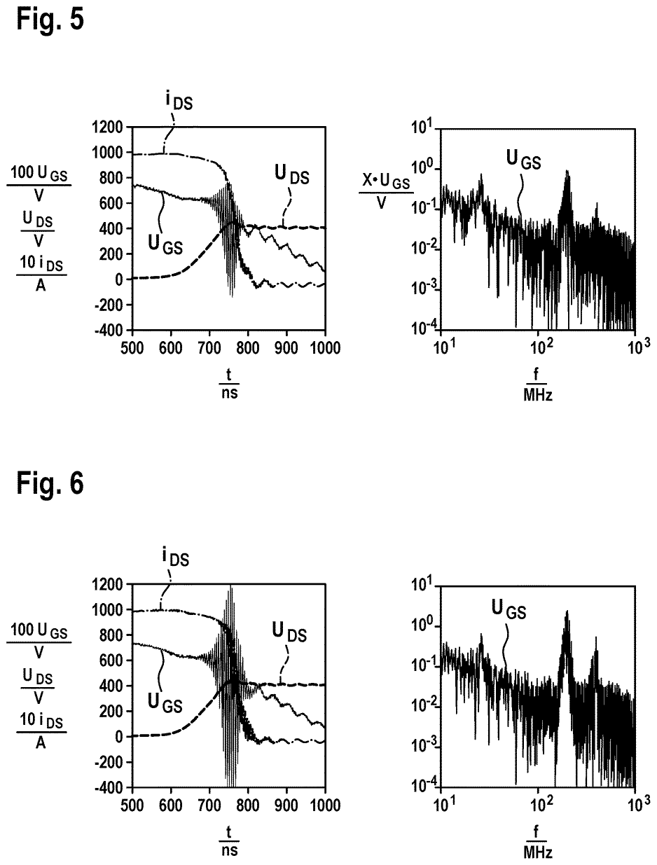

FIG. 5 to FIG. 8 each show diagrams of a gate-source voltage u_{GS}, a drain-source voltage u_{DS} and a drain-source current i_{DS} over time t and the spectral decomposition of the gate-source voltage u_{GS} over frequency f. Note that in each right diagram, the gate-source voltage u_{GS} is normalized by a factor x. All signals have been measured at the external pads or auxiliary terminals of the power module 1, respectively.

FIG. 5 refers to a power module corresponding to the power module 1 according to the first embodiment without a shielding structure. As can be seen, a switching signal causing the power module to turn off causes significant oscillations of the gate-source-voltage due to inductive feedback loops formed by connecting the dies 2a to 2h in parallel in combination with non-linear voltage-dependent capacitances of the transistors. It can be observed that the oscillations have a peak at 198 MHz with a normalized magnitude a=1.

FIG. 6 refers to a power module corresponding to the power module 1 according to the first embodiment with a shielding structure made of a manganese-zinc ferrite. Such a shielding structure even amplifies the oscillations to a normalized magnitude a=2.26 with a slight shift in the peak to 196 MHz. This negative effect is caused by the real part of the complex permeability of such a ferrite having a relatively high value

$${μ}_{r}^{′}$$

at the peak and a maximum of the imaginary part of the complex permeability

$${μ}_{r}^{″}$$

at a very low frequency of about 2 MHz. Therefore, a nickel-zinc-based ferrite having, e.g.,

$${μ}_{r}^{′} = 2 …3$$

at the peak frequency and a maximum of

$${μ}_{r}^{″}$$

at 70 . . . 100 MHz being substantially closer to the peak frequency is proposed as material of the shielding structure 13 according to the embodiments.

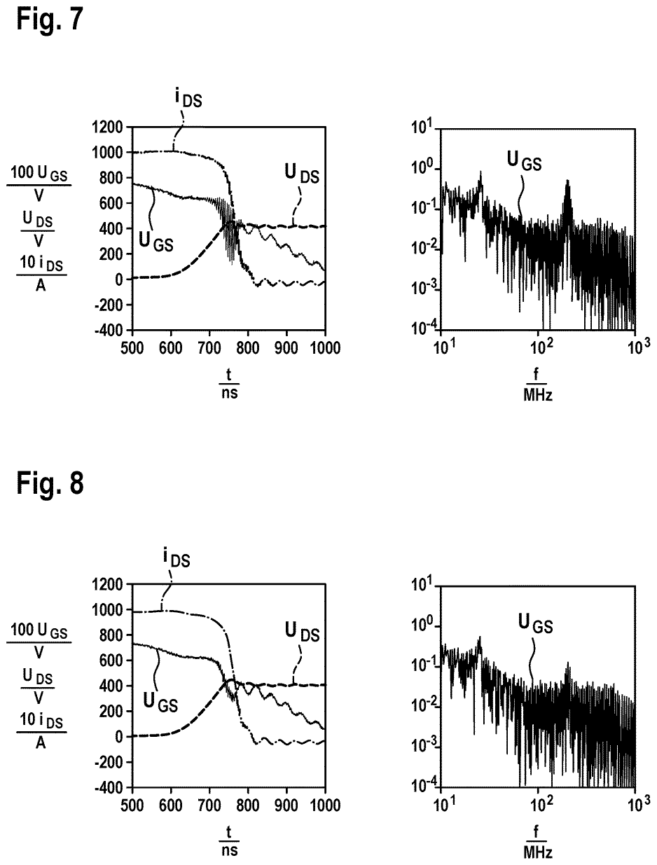

FIG. 7 refers to the first embodiment with the shielding structure 13 being made of a nickel-iron soft ferromagnetic alloy such as permalloy or mu-metal. As can be seen, although such an alloy is usually not considered to have pronounced high frequency properties in the VHF range, the oscillation is attenuated to a normalized magnitude a=0.47 with a shift of the peak to 200 MHz.

FIG. 8 refers to the first embodiment with the shielding structure 13 being made of electrical steel. The electrical steel is M330-35 in compliance with EN 10106:2015. As can be seen, although such an electrical steel is usually not considered to have pronounced high frequency properties in the VHF range, the oscillation is attenuated to a normalized magnitude a=0.14 with a shift of the peak to 208 MHz.

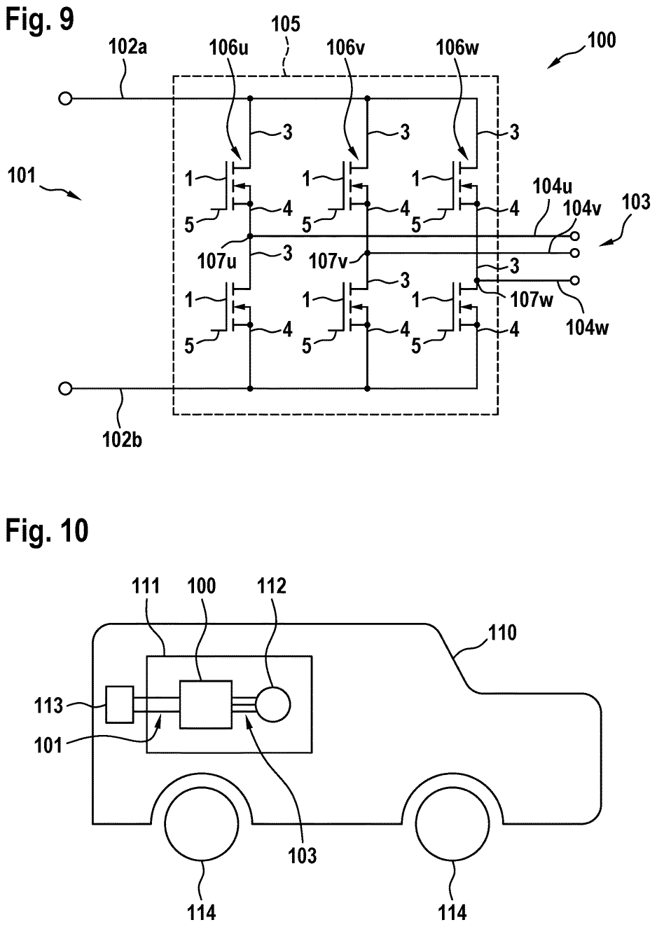

FIG. 9 is a block diagram of an embodiment of an electric power converter 100.

The electric power converter 100 forms an inverter and comprises a DC port 101 with two lines 102a, 102b for a DC voltage, an AC port 103 with multiple phase conductors 104u, 104v, 104w for an AC voltage and a power section 105.

The power section 105 comprises a plurality of switching elements. The switching elements are interconnected to a half-bridges 106u, 106v, 106w for each phase conductor 104u, 104v, 104w. Each half-bridge 106u, 106v, 106w is formed by a power module 1 according to any of the above embodiments so that each switching element is formed by one of the arrangements 2, 2′. Further, each half-bridge 106u,106 v, 106 is connected to the DC 101 and each phase conductor 106u, 106v, 106w is connected to a central tap 107u, 107v, 107w between the switching elements of one of the half-bridges 106u, 106v, 106w. Therein, the connections between the switching elements are realized by the electrical connectors 7e (see FIG. 1).

FIG. 10 is a principle drawing of an electric vehicle 110 with an embodiment of an electric drive 111.

The electric drive 111 comprises an electric machine 112 configured to propel the vehicle 110 and an electric power converter 100 according to the above embodiment. The electric machine 112 is connected to the AC port 103 for supplying the electric machine 112. Further, the DC port 101 is connected to a high-voltage battery 113 of the vehicle 110.

The electric vehicle 110 comprises wheels 114 being directly or indirectly, e.g., via a transmission, coupled with the electric drive 111 so as to rotate the wheels 114. According to the embodiment, the electric vehicle 110 is a battery electric vehicle (BEV). Alternatively, the electric vehicle 110 may additionally comprise a combustion engine, therein forming a hybrid vehicle. Further, the electric vehicle 110 may comprise a fuel cell supplying the electric power converter 100.

1. Power module comprising at least one arrangement of multiple dies each forming a transistor with a switching path, each die having a first terminal, a second terminal and a control terminal, the switching path being formed between the first terminal and the second terminal and being switchable depending on a voltage across the control terminal and the second terminal, the transistors being connected in parallel by the first terminals being connected with each other and the second terminals being connected to each other,
wherein
the at least one arrangement comprises a shielding structure that covers at least two of the dies at least partially, the shielding structure comprising or consisting of one material or multiple materials chosen from a group consisting of a nickel-zinc-based ferrite, a nickel-iron soft ferromagnetic alloy and an electrical steel.

2. module according to claim 1, wherein
electrical connections between the dies form a resonant circuit with one or multiple resonance frequencies of at least 100 MHz and feedback loops that form an inductive coupling between the second terminals on the one hand and the first terminals and/or control terminals on the other hand, the shielding structure being configured to reduce the inductive coupling.

3. Power module according to claim 1, wherein
the nickel-zinc-based ferrite has a complex permeability with a real part and an imaginary part, wherein
within a frequency range between 10 MHz and 1 GHz, there is a maximum of the imaginary part and/or
at a frequency of 100 MHz, preferably 50 MHz, more preferably 10 MHz, the real part of the complex permeability is reduced compared to its value for frequencies approaching zero.

4. Power module according to claim 1, wherein
the shielding structure is plate-shaped.

5. Power module according to claim 1,
the at least one arrangement further comprising an electrically conductive pad, to which the second terminals are connected, and
an electrically conductive second pad, to which the first terminals are connected, wherein the shielding structure does not cover the die that has the smallest distance to the first pad and/or
an electrically conductive trace to which the control terminals are connected, wherein the shielding structure does not cover the die that has the smallest distance to the first pad or to an electrically conductive further pad of the power module, to which further pad kelvin terminals of the dies are connected.

6. Power module according to claim 1, wherein
the shielding structure covers each die at least partially.

7. Power module according to claim 1, wherein
the shielding structure covers the at least two dies fully.

8. Power module according to claim 1, further comprising a single body formed by electrically insulating molding material, the body covering the dies and/or electrical connections between the dies, the body embedding the shielding structure.

9. Power module, according to claim 1, further comprising a carrier, on which the dies are mounted, the at least two dies being arranged between the carrier and the shielding structure.

10. Power module according to claim 1,
the at least one arrangement further comprising a support structure mounting the shielding structure.

11. Power module according to claim 9, wherein
the support structure is mounted on the carrier.

12. Power module according to claim 10, wherein
the support structure is
electrically insulating and/or
a frame, upon which the shielding structure is arranged, or a multiplicity of domes each supporting the shielding structure selectively.

13. Power module according to claim 1, wherein
a first arrangement and a second arrangement are provided, the first terminals of the first arrangement being connected to the second terminals of the second arrangement so as to form a half-bridge.

14. Electric power converter, comprising:
a DC port for a DC voltage;
an AC port with multiple phase conductors for an AC voltage; and
a power section comprising a plurality of switching elements being interconnected to a half-bridge for each phase conductor, each half-bridge being connected to the DC port and each phase conductor being connected to a central tap between the switching elements of one of the half-bridges;
wherein each switching element or each half-bridge is formed by a power module according to claim 1.

15. Electric drive for a transportation mean, for example for a vehicle or for a bicycle, comprising an electric machine configured to propel the transportation mean and an electric power converter according to claim 14, the electric machine being connected to the AC port of the electric power converter for supplying the electric machine with the AC voltage.

16. Power module according to claim 2, wherein
the nickel-zinc-based ferrite has a complex permeability with a real part and an imaginary part, wherein
within a frequency range between 10 MHz and 1 GHz, there is a maximum of the imaginary part and/or
at a frequency of 100 MHz, preferably 50 MHz, more preferably 10 MHz, the real part of the complex permeability is reduced compared to its value for frequencies approaching zero.

17. Power module according to claim 2, wherein
the shielding structure is plate-shaped.

18. Power module according to claim 2,
the at least one arrangement further comprising an electrically conductive pad, to which the second terminals are connected, and
an electrically conductive second pad, to which the first terminals are connected, wherein the shielding structure does not cover the die that has the smallest distance to the first pad and/or
an electrically conductive trace, to which the control terminals are connected,
wherein the shielding structure does not cover the die that has the smallest distance to the first pad or to an electrically conductive further pad of the power module, to which further pad kelvin terminals of the dies are connected.

19. Power module according to claim 2, wherein
the shielding structure covers each die at least partially.

20. Power module according to claim 2, wherein
the shielding structure covers the at least two dies fully.
